(19) United States
(12) Patent Application Publication
(10) Pub. No.: US 2022/0189771 A1
(43) Pub. Date: Jun. 16, 2022

(54) UNDERLAYER FILM FOR SEMICONDUCTOR DEVICE FORMATION

(71) Applicant: Applied Materials, Inc., Santa Clara, CA (US)

(72) Inventors: Gene LEE, San Jose, CA (US); Gabriela ALVA, Santa Clara, CA (US)

(21) Appl. No.: 17/157,548

(22) Filed: Jan. 25, 2021

Related U.S. Application Data
(60) Provisional application No. 63/123,882, filed on Dec. 10, 2020.

(51) Int. Cl. H01L 21/033; H01L 21/311

(52) U.S. Cl. CPC H01L 21/0332; H01L 21/0338; H01L 21/31122

(57) ABSTRACT

A structure includes an underlayer formed on a substrate, a mandrel layer formed on the underlayer, and a spacer layer formed on the mandrel layer. The underlayer includes a first material, and the spacer layer includes a second material. The first material is resistant to etching gases used in a first etch process to remove portions of the spacer layer and a second etch process to remove the mandrel layer.

### CROSS-REFERENCE TO RELATED APPLICATIONS

This application claims priority to U.S. Provisional Application Ser. No. 63/123,882 filed on Dec. 10, 2020, which is herein incorporated by reference in its entirety.

### BACKGROUND

### Field

Examples of the present disclosure generally relate to forming a semiconductor device. Particularly, embodiments of the present disclosure provide methods for forming nanostructures with reduced defects.

### Description of the Related Art

In the manufacture of integrated circuits (IC), or chips, patterns representing different layers of the chip are created by a chip designer. A series of photomasks are created from these patterns in order to transfer the design of each semiconductor layer onto a semiconductor substrate during the manufacturing process by optical lithography. The masks are then used to transfer the circuit patterns for each layer onto a semiconductor substrate by wet or dry etching. These layers are built up using a sequence of lithography-and-etch processes and translated into nanostructures that comprise each completed chip.

However, in a wet or dry etching process, an underlayer that is disposed underneath a layer may not have a low enough etch rate in an etch process to pattern the semiconductor layer and may be etched together with the semiconductor layer. This may form a recess in the underlayer, causing defects in a resulting chip, thus eventually leading to device failure.

Therefore, there is a need for an underlayer which has a substantially low etch rate in the etch process to pattern a layer, and methods for forming nanostructures using such an underlayer.

### SUMMARY

Embodiments of the present disclosure provide a structure. The structure includes an underlayer formed on a substrate, a mandrel layer formed on the underlayer, and a spacer layer formed on the mandrel layer. The underlayer includes a first material, and the spacer layer includes a second material. The first material is resistant to etching gases used in a first etch process to remove portions of the spacer layer and a second etch process to remove the mandrel.

Embodiments of the present disclosure also provide an underlayer for use in forming a structure. The underlayer includes a first material formed on a substrate, the first material being resistant to etching gases used in a first etch process to remove portions of a second material formed on the first material.

Embodiments of the present disclosure further provide a method for forming a structure on a substrate. The method includes performing a deposition process, including conformally depositing a spacer layer on a mandrel layer and a surface of an underlayer that is exposed from the mandrel layer, performing a first etch process, including removing portions of the spacer layer from a top surface of the mandrel layer and the surface of the underlayer without removing the spacer layer from sidewalls of the mandrel layer, and performing a second etch process to remove the mandrel layer without removing the spacer layer. There is insubstantial or no recess in the underlayer caused by the first etch and the second etch.

### BRIEF DESCRIPTION OF THE DRAWINGS

So that the manner in which the above recited features of embodiments of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 depicts a processing chamber that may be utilized to perform a deposition process according to one embodiment.

FIG. 2 depicts a processing chamber that may be utilized to perform a patterning process according to one embodiment.

FIG. 3 is a flow diagram of a method 300 for manufacturing a nanostructure 400 according to one embodiment.

FIGS. 4A, 4B, 4C, 4D, 4E, 4F, and 4G are cross-sectional views of a portion of a nanostructure according to one embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

The embodiments described herein provide materials for an underlayer that has a low etch rate in an etch process to remove portions of a layer formed on the underlayer, and methods of forming nanostructures using such an underlayer. A layer to be etched may be formed of carbon containing material, silicon nitride, doped silicon containing material, or silicon oxide. An underlayer may be formed of aluminum oxide (Al₂O₃), tin oxide (SnO₂), tungsten carbide (WC), boron (B), silicon containing dielectric material such as silicon nitride (Si₃N₄), silicon carbon nitride (SiCN), or silicon boron nitride (SiBN), boron containing dielectric material such as boron oxide (B₂O₃) or boron nitride (BN), or ceramic material such as zirconium dioxide (ZrO₂) or titanium nitride (TiN). Due to the low etch rate of the underlayer, the underlayer remains undamaged (e.g., without forming a recess therein) while the semiconductor layer formed on the underlayer is patterned.

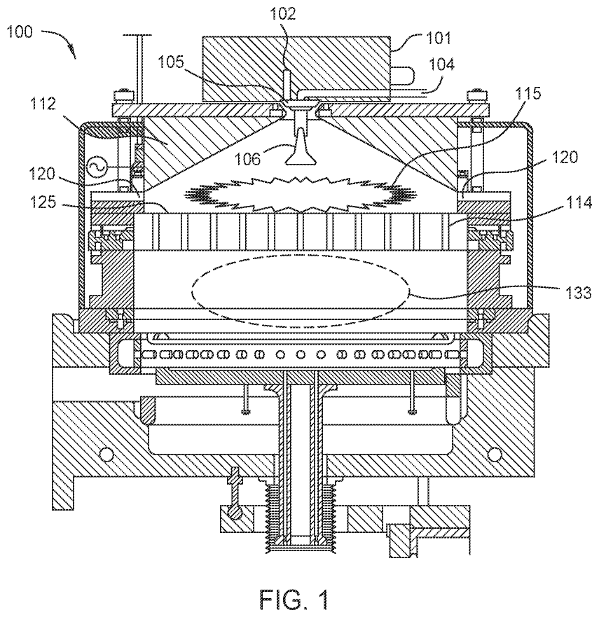

FIG. 1 is a cross-sectional view of one embodiment of a chemical vapor deposition chamber 100 with partitioned plasma generation regions. The chemical vapor deposition chamber 100 may be utilized to deposit a silicon containing layer, such as silicon oxide, silicon nitride, silicon boride, silicon carbide, silicon oxynitride, or silicon oxycarbide, onto a substrate. During a deposition process, a process gas may be flowed into a first plasma region 115 through a gas inlet assembly 105. The process gas may be excited prior to entering the first plasma region 115 within a remote plasma system (RPS) 101. The deposition chamber 100 includes a lid 112 and showerhead 125. The lid 112 is depicted with an applied AC voltage source, and the showerhead 125 is grounded, consistent with plasma generation in the first plasma region 115. An insulating ring 120 is positioned between the lid 112 and the showerhead 125 enabling an inductively coupled plasma (ICP) or a capacitively coupled plasma (CCP) to be formed in the first plasma region 115. The lid 112 and showerhead 125 are shown with the insulating ring 120 in between, which allows an AC potential to be applied to the lid 112 relative to the showerhead 125.

The lid 112 may be a dual-source lid featuring two distinct gas supply channels within the gas inlet assembly 105. A first gas supply channel 102 carries a gas that passes through the remote plasma system (RPS) 101, while a second gas supply channel 104 bypasses the RPS 101. The first gas supply channel 102 may be used for the process gas, and the second gas supply channel 104 may be used for a treatment gas. The gases that flow into the first plasma region 115 may be dispersed by a baffle 106.

A fluid, such as a precursor, may be flowed into a second plasma region 133 of the deposition chamber 100 through the showerhead 125. Excited species derived from the precursor in the first plasma region 115 travel through apertures 114 in the showerhead 125 and react with the precursor flowing into the second plasma region 133 from the showerhead 125. Little or no plasma is present in the second plasma region 133. Excited derivatives of the precursor combine in the second plasma region 133 to form a flowable dielectric material on the substrate. As the dielectric material grows, more recently added material possesses a higher mobility than underlying material. Mobility decreases as organic content is reduced by evaporation. Gaps may be filled by the flowable dielectric material using this technique without leaving traditional densities of organic content within the dielectric material after deposition is completed. A curing step may still be used to further reduce or remove the organic content from the deposited film.

Exciting the precursor in the first plasma region 115 alone or in combination with the remote plasma system (RPS) 101 provides several benefits. The concentration of the excited species derived from the precursor may be increased within the second plasma region 133 due to the plasma in the first plasma region 115. This increase may result from the location of the plasma in the first plasma region 115. The second plasma region 133 is located closer to the first plasma region 115 than the remote plasma system (RPS) 101, leaving less time for the excited species to leave excited states through collisions with other gas molecules, walls of the chamber and surfaces of the showerhead.

The uniformity of the concentration of the excited species derived from the precursor may also be increased within the second plasma region 133. This may result from the shape of the first plasma region 115, which is more similar to the shape of the second plasma region 133. Excited species created in the remote plasma system (RPS) 101 travel greater distances in order to pass through apertures 114 near the edges of the showerhead 125 relative to species that pass through apertures 114 near the center of the showerhead 125. The greater distance results in a reduced excitation of the excited species and, for example, may result in a slower growth rate near the edge of a substrate. Exciting the precursor in the first plasma region 115 mitigates this variation.

In addition to the precursors, there may be other gases introduced at different times for various purposes. For example, a treatment gas may be introduced to remove unwanted species from the chamber walls, the substrate, the deposited film and/or the film during deposition. The treatment gas may comprise at least one or more of the gases selected from the group consisting of H₂, an H₂/N₂ mixture, NH₃, NH₄OH, O₃, O₂, H₂O₂ and water vapor. The treatment gas may be excited in a plasma, and then used to reduce or remove a residual organic content from the deposited film. In other examples, the treatment gas may be used without a plasma. When the treatment gas includes water vapor, the delivery may be achieved using a mass flow meter (MFM) and injection valve, or by utilizing other suitable water vapor generators.

In one embodiment, a silicon containing layer may be deposited by introducing silicon containing precursors and reacting processing precursors in the second plasma region 133. Examples of dielectric material precursors are silicon containing precursors including silane, disilane, methylsilane, dimethylsilane, trimethylsilane, tetramethylsilane, tetraethoxysilane (TEOS), triethoxysilane (TES), octamethylcyclotetrasiloxane (OMCTS), tetramethyl-disiloxane (TMDSO), tetramethylcyclotetrasiloxane (TMCTS), tetramethyl-diethoxyl-disiloxane (TMDDSO), dimethyl-dimethoxyl-silane (DMDMS) or combinations thereof. Additional precursors for the deposition of silicon nitride include SiₓN_{y}H_{z} containing precursors, such as sillyl-amine and its derivatives including trisillylamine (TSA) and disillylamine (DSA), SiₓN_{y}H_{z}O_{zz} containing precursors, SiₓN_{y}H_{z}Cl_{zz} containing precursors, or combinations thereof.

Processing precursors may include boron containing compounds, hydrogen containing compounds, oxygen containing compounds, nitrogen containing compounds, or combinations thereof. Suitable examples of the boron containing compounds include BH₃, B₂H₆, BF₃, BCl₃, and the like. Examples of suitable processing precursors include one or more of compounds selected from the group consisting of H₂, a H₂/N₂ mixture, NH₃, NH₄OH, O₃, O₂, H₂02, N₂, NₓH_{y} compounds including N₂H₄ vapor, NO, N₂O, NO₂, water vapor, or combinations thereof. The processing precursors may be plasma exited, such as in the RPS unit, to include N* and/or H* and/or O* containing radicals or plasma, for example, NH₃, NH₂*, NH*, N*, H*, O*, N*O*, or combinations thereof. The process precursors may alternatively, include one or more of the precursors described herein.

The processing precursors may be plasma excited in the first plasma region 115 to produce process gas plasma and radicals including B*, N* and/or H* and/or O* containing radicals or plasma, or combinations thereof. Alternatively, the processing precursors may already be in a plasma state after passing through a remote plasma system prior to introduction to the first plasma region 115.

The excited processing precursor is then delivered to the second plasma region 133 for reaction with the precursors though apertures 114. Once in the processing volume, the processing precursor may mix and react to deposit the dielectric materials on the substrate.

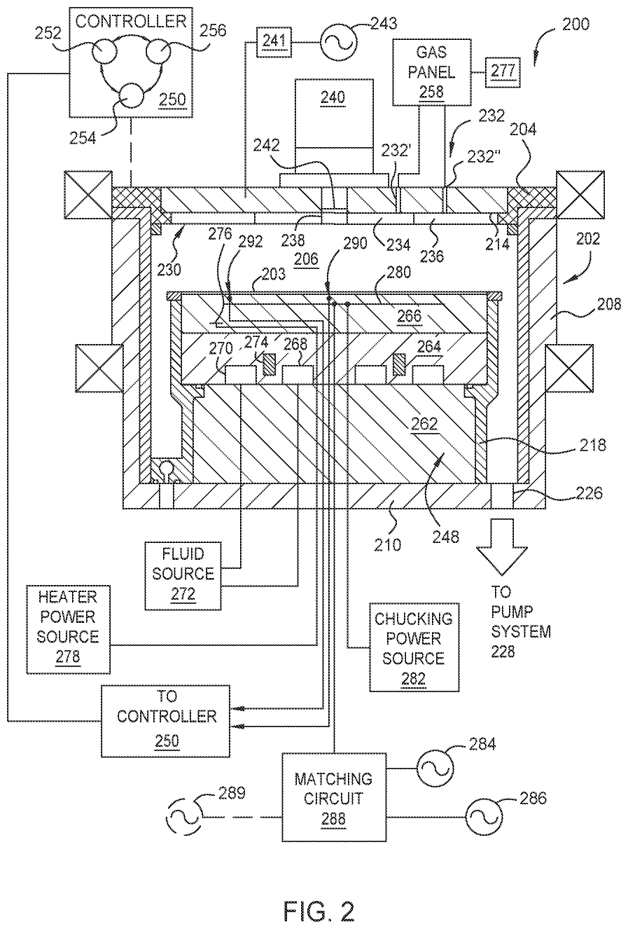

FIG. 2 is a sectional view of one example of a processing chamber 200 suitable for performing a patterning process, such as anisotropic etching and isotropic etching. Suitable processing chambers that may be adapted for use with the methods disclosed herein include, for example, a CENTRIS® SYM3™ processing chamber available from Applied Materials, Inc. of Santa Clara, Calif. Although the processing chamber 200 is shown including a plurality of features that enable superior etching performance, it is contemplated that other processing chambers may be adapted to benefit from one or more of the inventive features disclosed herein.

The processing chamber 200 includes a chamber body 202 and a lid 204 which enclose an interior volume 206. The chamber body 202 is typically fabricated from aluminum, stainless steel or other suitable material. The chamber body 202 generally includes sidewalls 208 and a bottom 210. A substrate support pedestal access port (not shown) is generally defined in a sidewall 208 and selectively sealed by a slit valve to facilitate entry and egress of a substrate 203 from the processing chamber 200. An exhaust port 226 is defined in the chamber body 202 and couples the interior volume 206 to a vacuum pump system 228. The vacuum pump system 228 generally includes one or more pumps and throttle valves utilized to evacuate and regulate the pressure of the interior volume 206 of the processing chamber 200. In one implementation, the vacuum pump system 228 maintains the pressure inside the interior volume 206 at operating pressures typically between about 10 mTorr to about 500 Torr.

The lid 204 is sealingly supported on the sidewall 208 of the chamber body 202. The lid 204 may be opened to allow excess to the interior volume 206 of the processing chamber 200. The lid 204 includes a window 242 that facilitates optical process monitoring. In one implementation, the window 242 is comprised of quartz or other suitable material that is transmissive to a signal utilized by an optical monitoring system 240 mounted outside the processing chamber 200.

The optical monitoring system 240 is positioned to view at least one of the interior volume 206 of the chamber body 202 and/or the substrate 203 positioned on a substrate support pedestal assembly 248 through the window 242. In one embodiment, the optical monitoring system 240 is coupled to the lid 204 and facilitates an integrated deposition process that uses optical metrology to provide information that enables process adjustment to compensate for incoming substrate pattern feature inconsistencies (such as thickness, and the like), and provide process state monitoring (such as plasma monitoring, temperature monitoring, and the like) as needed. One optical monitoring system that may be adapted to benefit from the disclosure is the EyeD® full-spectrum, interferometric metrology module, available from Applied Materials, Inc., of Santa Clara, Calif.

A gas panel 258 is coupled to the processing chamber 200 to provide process and/or cleaning gases to the interior volume 206. In the example depicted in FIG. 2, inlet ports 232′, 232″ are provided in the lid 204 to allow gases to be delivered from the gas panel 258 to the interior volume 206 of the processing chamber 200. In one implementation, the gas panel 258 is adapted to provide fluorinated process gas through the inlet ports 232′, 232″ and into the interior volume 206 of the processing chamber 200. In one implementation, the process gas provided from the gas panel 258 includes at least a fluorinated gas, chlorine, and a carbon containing gas, an oxygen gas, a nitrogen containing gas and a chlorine containing gas. Examples of fluorinated and carbon containing gases include CH₃F, CH₂F₂, and CF₄. Other fluorinated gases may include one or more of C₂F, C₄F₆, C₃F₈, and C₅F₈. Examples of the oxygen containing gas include O₂, CO₂, CO, N₂O, NO₂, O₃, H₂O, and the like. Examples of the nitrogen containing gas include N₂, NH₃, N₂O, NO₂, and the like. Examples of the chlorine containing gas include HCl, Cl₂, CCl₄, CHCl₃, CH₂Cl₂, CH₃Cl, and the like. Suitable examples of the carbon containing gas include methane (CH₄), ethane (C₂H₆), ethylene (C₂H₄), and the like.

A showerhead assembly 230 is coupled to an interior surface 214 of the lid 204. The showerhead assembly 230 includes a plurality of apertures that allow the gases flowing through the showerhead assembly 230 from the inlet ports 232′, 232″ into the interior volume 206 of the processing chamber 200 in a predefined distribution across the surface of the substrate 203 being processed in the processing chamber 200.

A remote plasma source 277 may be optionally coupled to the gas panel 258 to facilitate dissociating gas mixture from a remote plasma prior to entering into the interior volume 206 for processing. A RF source power 243 is coupled through a matching network 241 to the showerhead assembly 230. The RF source power 243 typically is capable of producing up to about 3000 W at a tunable frequency in a range from about 50 kHz to about 200 MHz.

The showerhead assembly 230 additionally includes a region transmissive to an optical metrology signal. The optically transmissive region or passage 238 is suitable for allowing the optical monitoring system 240 to view the interior volume 206 and/or the substrate 203 positioned on the substrate support pedestal assembly 248. The passage 238 may be a material, an aperture or plurality of apertures formed or disposed in the showerhead assembly 230 that is substantially transmissive to the wavelengths of energy generated by, and reflected back to, the optical monitoring system 240.

In one implementation, the showerhead assembly 230 is configured with a plurality of zones that allow for separate control of gas flowing into the interior volume 206 of the processing chamber 200. In the example illustrated in FIG. 2, the showerhead assembly 230 has an inner zone 234 and an outer zone 236 that are separately coupled to the gas panel 258 through separate inlet ports 232′, 232″.

The substrate support pedestal assembly 248 is disposed in the interior volume 206 of the processing chamber 200 below the gas distribution (showerhead) assembly 230. The substrate support pedestal assembly 248 holds the substrate 203 during processing. The substrate support pedestal assembly 248 generally includes a plurality of lift pins (not shown) disposed therethrough that are configured to lift the substrate 203 from the substrate support pedestal assembly 248 and facilitate exchange of the substrate 203 with a robot (not shown) in a conventional manner. An inner liner 218 may closely circumscribe the periphery of the substrate support pedestal assembly 248.

In one implementation, the substrate support pedestal assembly 248 includes a mounting plate 262, a base 264 and an electrostatic chuck 266. The mounting plate 262 is coupled to the bottom 210 of the chamber body 202 and includes passages for routing utilities, such as fluids, power lines and sensor leads, among others, to the base 264 and the electrostatic chuck 266. The electrostatic chuck 266 comprises at least one clamping electrode 280 for retaining the substrate 203 below showerhead assembly 230. The electrostatic chuck 266 is driven by a chucking power source 282 to develop an electrostatic force that holds the substrate 203 to the chuck surface, as is conventionally known. Alternatively, the substrate 203 may be retained to the substrate support pedestal assembly 248 by clamping, vacuum or gravity.

At least one of the base 264 or electrostatic chuck 266 may include at least one optional embedded heater 276, at least one optional embedded isolator 274, and a plurality of conduits 268, 270 to control the lateral temperature profile of the substrate support pedestal assembly 248. The conduits 268, 270 are fluidly coupled to a fluid source 272 that circulates a temperature regulating fluid therethrough. The heater 276 is regulated by a power source 278. The conduits 268, 270 and heater 276 are utilized to control the temperature of the base 264, thereby heating and/or cooling the electrostatic chuck 266 and ultimately, the temperature profile of the substrate 203 disposed thereon. The temperature of the electrostatic chuck 266 and the base 264 may be monitored using a plurality of temperature sensors 290, 292. The electrostatic chuck 266 may further comprise a plurality of gas passages (not shown), such as grooves, that are formed in a substrate support pedestal supporting surface of the electrostatic chuck 266 and fluidly coupled to a source of a heat transfer (or backside) gas, such as He. In operation, the backside gas is provided at controlled pressure into the gas passages to enhance the heat transfer between the electrostatic chuck 266 and the substrate 203.

In one implementation, the substrate support pedestal assembly 248 is configured as a cathode and includes the electrode 280 that is coupled to a plurality of RF bias power sources 284, 286. The RF bias power sources 284, 286 are coupled between the electrode 280 disposed in the substrate support pedestal assembly 248 and another electrode, such as the showerhead assembly 230 or ceiling (lid 204) of the chamber body 202. The RF bias power excites and sustains a plasma discharge formed from the gases disposed in the processing region of the chamber body 202.

In the example depicted in FIG. 2, the dual RF bias power sources 284, 286 are coupled to the electrode 280 disposed in the substrate support pedestal assembly 248 through a matching circuit 288. The signal generated by the RF bias power sources 284, 286 is delivered through matching circuit 288 to the substrate support pedestal assembly 248 through a single feed to ionize the gas mixture provided in the plasma processing chamber 200, thereby providing ion energy necessary for performing a deposition or other plasma enhanced process. The RF bias power sources 284, 286 are generally capable of producing an RF signal having a frequency of from about 50 kHz to about 200 MHz and a power between about 0 Watts and about 5000 Watts. An additional bias power source 289 may be coupled to the electrode 280 to control the characteristics of the plasma.

In one mode of operation, the substrate 203 is disposed on the substrate support pedestal assembly 248 in the plasma processing chamber 200. A process gas and/or gas mixture is introduced into the chamber body 202 through the showerhead assembly 230 from the gas panel 258. The vacuum pump system 228 maintains the pressure inside the chamber body 202 while removing deposition by-products.

A controller 250 is coupled to the processing chamber 200 to control operation of the processing chamber 200. The controller 250 includes a central processing unit (CPU) 252, a memory 254, and a support circuit 256 utilized to control the process sequence and regulate the gas flows from the gas panel 258. The CPU 252 may be any form of general purpose computer processor that may be used in an industrial setting. The software routines can be stored in the memory 254, such as random access memory, read only memory, floppy, or hard disk drive, or other form of digital storage. The support circuit 256 is conventionally coupled to the CPU 252 and may include cache, clock circuits, input/output systems, power supplies, and the like. Bi-directional communications between the controller 250 and the various components of the processing chamber 200 are handled through numerous signal cables.

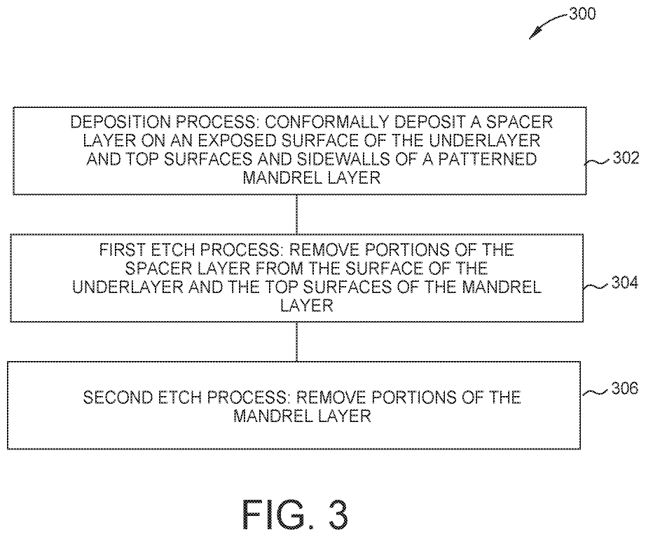

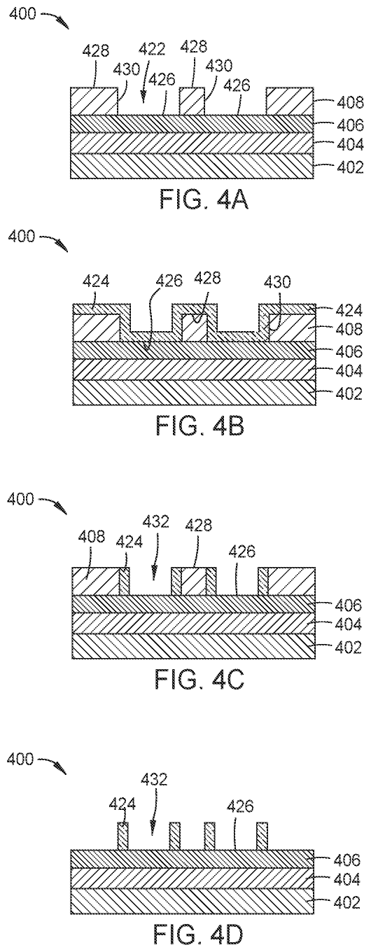

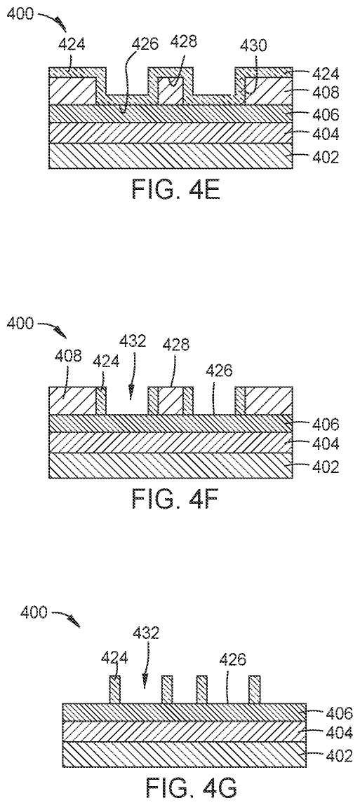

FIG. 3 is a flow diagram of a method 300 for forming a nanostructure 400 according to one embodiment. FIGS. 4A, 4B, 4C, 4D, 4E, 4F, and 4G are cross-sectional views of a portion of the nanostructure 400 corresponding to various stages of the method 300. The method 300 may be utilized to form features in a material layer, such as a contact dielectric layer, a gate electrode layer, a gate dielectric layer, a STI insulating layer, inter-metal layer (IML), or any suitable layers. Alternatively, the method 300 may be beneficially utilized to etch any other types of structures as needed.

As shown in FIG. 4A, the nanostructure 400 includes a substrate 402, an interfacial layer 404 disposed on the substrate 402, an underlayer 406 disposed on the interfacial layer 404, and a mandrel layer 408 disposed on the underlayer 406.

The substrate 402 may include a material such as crystalline silicon (e.g., Si<100> or Si<111>), silicon oxide, strained silicon, silicon germanium, doped or undoped polysilicon, doped or undoped silicon wafers and patterned or non-patterned wafers, silicon on insulator (SOI), carbon doped silicon oxides, silicon nitride, doped silicon, germanium, gallium arsenide, glass, or sapphire. The substrate 402 may have various dimensions, such as 200 mm, 300 mm, 450 mm or other diameter wafers, as well as, rectangular or square panels.

The interfacial layer 404 may be formed of silicon oxide (SiO₂), tetra-ethyl-orthosilicate (TEOS), silicon oxynitride (SiON), silicon boride (SiBx), silicon carbonitride (SiCN), boron carbide (BC), amorphous carbon, boron nitride (BN), boron carbon nitride (BCN), carbon doped oxides, porous silicon dioxide, silicon nitride (SiN), oxycarbonitrides, polymers, phosphosilicate glass, fluorosilicate (SiOF) glass, organosilicate glass (SiOCH), other suitable oxide material, other suitable carbide material, other suitable oxycarbide material, or other suitable oxynitride material.

The underlayer 406 is an etch stop layer that provides etch selectivity to a spacer layer 424 (shown in FIGS. 4B, 4C, and 4E) that is deposited on the mandrel layer 408, as described below, in a subsequent etch process.

The mandrel layer 408 may be formed of a carbon containing material, such as amorphous carbon, spin-on carbon (SoC), or other suitable carbon containing material, and patterned with openings 422 by using any appropriate a lithography-and-etch process. In one particular example, the mandrel layer 408 is formed of Saphira™ Advanced Patterning Film (APF) carbon hardmask produced by Applied Materials, Inc., located in Santa Clara, Calif.

The spacer layer 424 may be formed of silicon containing dielectric material, such as silicon nitride (Si₃N₄), silicon oxide (SiO₂), or silicon boride (SiB). In some other embodiments, the spacer layer 424 may be formed of doped silicon containing material, such as a boron doped silicon material, phosphorus doped silicon, or other suitable group III, group IV or group V doped silicon material. In some embodiments, the underlayer 406 is formed of a first type of material that has a significantly low etch rate in an etch process to remove portions of the spacer layer 424 formed of silicon nitride (Si₃N₄) with a fluorine containing etch gas. Thus, the underlayer 406 is resistant to etching gases used in the etch process. Suitable examples of the first type of material include aluminum oxide (Al₂O₃), tin oxide (SnO₂), boron (B), or tungsten carbide (WC). An etch rate of the underlayer 406 formed of the first type of material in an etch process with a fluorine containing etch gas such as CH₃F may be significantly lower than that of the spacer layer 424. In some other embodiments, the underlayer 406 is formed of a second type of material that has a significantly low etch rate in an etch process to remove portions of the spacer layer 424 formed of doped silicon containing material using a chlorine containing etching gas. Thus, the underlayer 406 is resistant to etching gases used in the etch process. Suitable examples of the second type of material include aluminum oxide (Al₂O₃). An etch rate of the underlayer 406 formed of the second type of material in an etch process using a chlorine containing etching gas may be significantly lower than that of the spacer layer 424. In some other embodiments, the underlayer 406 is formed of a third type of material that has a significantly low etch rate in an etch process to remove portions of the spacer layer 424 formed of silicon oxide (SiO₂) using a fluorine containing etch gas. Thus, the underlayer 406 is resistant to etching gases used in the etch process. Suitable examples of the third type of material include aluminum oxide (Al₂O₃), tin oxide (SnO₂), boron (B), or silicon nitride (Si₃N₄). An etch rate of the underlayer 406 formed of the third type or material in an etch process using a fluorine containing etching gas such as CF₄ may be significantly lower than that of the spacer layer 424.

In some other embodiments, the underlayer 406 may be formed of silicon containing dielectric material such as silicon carbon nitride (SiCN) or silicon boron nitride (SiBN), boron containing dielectric material such as boron oxide (B₂O₃) or boron nitride (BN), or ceramic material such as zirconium dioxide (ZrO₂) or titanium nitride (TiN), other suitable oxide material, other suitable carbide material, other suitable oxycarbide material, or other suitable oxynitride material that has a low etch rate in an etch process to remove portions of the spacer layer 424.

The method 300 begins in block 302 by a deposition process to deposit the spacer layer 424. The spacer layer 424 is conformally deposited on an exposed surface 426 of the underlayer 406 through the openings 422 of the mandrel layer 408, and top surfaces 428 and sidewalls 430 of the mandrel layer 408, as shown in FIG. 4B. The spacer layer 424 may be formed using any appropriate deposition process, such as atomic layer deposition (ALD), chemical vapor deposition (CVD), spin-on, physical vapor deposition (PVD), or the like.

In block 304, a first etch process is performed to remove portions of the spacer layer 424 from the surface 426 of the underlayer 406 and the top surfaces 428 of the mandrel layer 408, leaving only portions of the spacer layer 424 on the sidewalls 430 of the mandrel layer 408, as shown in FIG. 4B. This overburden etch process can be any appropriate etch process, such as a dry plasma etch process in a processing chamber, such as a CENTRIS® SYM3™ processing chamber available from Applied Materials, Inc. of Santa Clara, Calif. Due to the low etch rate of the underlayer 406 in an etch process to remove portions of the spacer layer 424, the underlayer 406 remains undamaged (e.g., without forming a recess in the underlayer 406) while the spacer layer 424 is patterned.

In the embodiments in which the spacer layer 424 is formed of silicon nitride (Si₃N₄), the etch process in block 304 is performed by simultaneously supplying a fluorine containing etching gas, an oxygen containing gas, and inert gas, such as helium (He), nitrogen (N₂), argon (Ar), or hydrogen (H₂), in the processing chamber. Suitable examples of the fluorine containing etching gas include CH₃F, NF₃, HF, CF₄, and SF₆. Suitable examples of the oxygen containing gas include O₂, NO₂, N₂O, O₃, SO₂, COS, CO, and CO₂. In one particular example, the fluorine containing etching gas includes CH₃F, the oxygen containing gas includes O₂, and the inert gas includes helium (He). In one example, O₂ and CH₃F gases may be supplied at flow rates of between about 5 sccm and about 200 sccm, for example, about 20 sccm, and between about 5 sccm and about 200 sccm, for example, about 50 sccm, respectively. Inert gas helium (He) may be supplied at a flow rate of between 10 sccm and about 1000 sccm, for example, about 200 sccm. The dry plasma etch process is performed for a duration of between about 5 second and about 350 seconds, for example, about 90 seconds. In one exemplary embodiment, a process pressure in the processing chamber is regulated between about 5 mTorr and about 150 mTorr, for example, about 60 mTorr.

In the embodiments in which the spacer layer 424 is formed of doped silicon containing material, the etch process in block 304 is performed by simultaneously supplying a chlorine containing etching gas, passivation gas, and inert gas, such as argon (Ar), nitrogen (N₂), helium (He), or hydrogen (H₂), in the processing chamber. Suitable examples of the chlorine containing etch gas include Cl₂, and BCl₃. The chlorine containing gas may include silicon containing compounds, such as SiCl₄, SiHCl₃, SiH₂Cl₂, SiH₃Cl, Si₂Cl₆, SiBr₄, SiHBr₃, SiH₂Br₂, SiH₃Br, SiH₄, Si₂H₆, Si₃H₈, Si₄H₁₀, SiHI₂, SiH₂I, C₄H₁₂Si, and Si(C₂H₃O₂)₄. Suitable examples of the passivation gas include HBr, BCl₃, SF₆, and H₂S. In one particular example, the chlorine containing etching gas includes Cl₂, the passivation gas includes HBr, and the inert gas includes argon (Ar) and nitrogen (N₂). In one example, HBr and Cl₂ gases may be supplied at flow rates of between about 10 sccm and about 1000 sccm, for example, about 200 sccm, and between about 10 sccm and about 1000 sccm, for example, about 100 sccm, respectively. Inert gases argon (Ar) and nitrogen (N₂) may be supplied at a flow rate of between 10 sccm and about 1000 sccm, for example, about 100 sccm, and between about 5 sccm and about 500 sccm, for example, about 20 sccm, respectively. The dry plasma etch process is performed for a duration of between about 5 second and about 300 seconds, for example, about 35 seconds. In one exemplary embodiment, a process pressure in the processing chamber is regulated between about 3 mTorr and about 150 mTorr, for example, about 7 mTorr.

In the embodiments in which the spacer layer 424 is formed of silicon oxide (SiO₂), the etch process in block 304 is performed by supplying a fluorine containing etching gas in the processing chamber. Suitable examples of the fluorine containing etching gas include CF₄. In one example, CF₄ gas may be supplied at flow rates of between about 5 sccm and about 600 sccm, for example, about 200 sccm. The dry plasma etch process is performed for a duration of between about 5 second and about 300 seconds, for example, about 15 seconds. In one exemplary embodiment, a process pressure in the processing chamber is regulated between about 3 mTorr and about 150 mTorr, for example, about 4 mTorr.

In block 306, a second etch process is performed to remove the mandrel layer 408 as shown in FIG. 4D, by a dry plasma etch process in a processing chamber, such as a CENTRIS® SYM3™ processing chamber available from Applied Materials, Inc. of Santa Clara, Calif. In the second etch process in block 306, an etch rate of the underlayer 406 formed of the first type of material such as aluminum oxide (Al₂O₃), tin oxide (SnO₂), boron (B), or tungsten carbide (WC), the second type of material such as aluminum oxide (Al₂O₃), or the third type of material such as aluminum oxide (Al₂O₃), tin oxide (SnO₂), boron (B), or silicon nitride (Si₃N₄) is similar to or lower than that of an underlayer formed of conventional mask material such as Dielectric Anti-Reflection Coating (DARC)® 193 film.

The dry plasma etch process in block 306 is performed by simultaneously supplying an oxygen containing gas, and inert gas, such as argon (Ar), nitrogen (N₂), helium (He), or hydrogen (H₂), in the processing chamber. Suitable examples of the oxygen containing gas include O₂, NO₂, N₂O, O₃, SO₂, COS, CO, and CO₂. In one particular example, the oxygen containing gas includes O₂, and the inert gas includes argon (Ar).

During the dry plasma etch process in block 306, several process parameters may also be regulated. In one example, O₂ gas may be supplied at flow rates of between about 5 sccm and about 200 sccm, for example, about 300 sccm. Inert gas argon (Ar) may be supplied at a flow rate of between 10 sccm and about 1000 sccm, for example, about 100 sccm. The dry plasma etch process is performed for a duration of between about 10 second and about 200 seconds, for example, about 60 seconds. In one exemplary embodiment, a process pressure in the processing chamber is regulated between about 5 mTorr and about 150 mTorr, for example, about 45 mTorr.

In the embodiments described herein, materials for an underlayer that has a significantly low etch rate in an etch process to remove portions of a layer formed on the underlayer, and methods of forming structures using such an underlayer are provided. A layer to be etched may be formed of carbon containing material, silicon nitride, doped silicon containing material, or silicon oxide. An underlayer may be formed of aluminum oxide (Al₂O₃), tin oxide (SnO₂), tungsten carbide (WC), boron (B), or silicon nitride (Si₃N₄). Due to the significantly low etch rate of the underlayer, a recess that may be formed in the underlayer due to over-etching is significantly reduced, leading to reduced defects in resulting semiconductor devices. In some embodiments, the deposition process in block 302 and the first etch process in block 304 are performed without breaking the low pressure or vacuum environment in a processing system that includes a deposition chamber such as the chemical vapor deposition chamber 100, and a processing chamber, such as the processing chamber 200. The processes without breaking the low pressure or vacuum environment may reduce contamination due to moisture introduced in atmospheric environment and further reduce defects in formed semiconductor devices.

While the foregoing is directed to embodiments of the present disclosure, other and further embodiments of the disclosure may be devised without departing from the basic scope thereof, and the scope thereof is determined by the claims that follow.

What is claimed is:

1. A structure, comprising:
an underlayer formed on a substrate, the underlayer comprising a first material;
a mandrel layer formed on the underlayer; and
a spacer layer formed on the mandrel layer, the spacer layer comprising a second material, wherein
the first material is resistant to etching gases used in a first etch process to remove portions of the spacer layer and a second etch process to remove the mandrel layer.

2. The structure of claim 1, wherein
the second material comprises silicon nitride, and
the first etch process comprises an etch process using a fluorine containing etching gas.

3. The structure of claim 2, wherein
the first material comprises at least one of aluminum oxide, tin oxide, boron, or tungsten carbide.

4. The structure of claim 1, wherein
the second material comprises doped silicon containing material, and
the first etch process comprises an etch process using a chlorine containing etching gas.

5. The structure of claim 4, wherein
the first material comprises aluminum oxide.

6. The structure of claim 1, wherein
the second material comprises silicon oxide, and
the first etch process comprises an etch process using a fluorine containing etching gas.

7. The structure of claim 6, wherein
the first material comprises at least one of aluminum oxide, tin oxide, boron, or silicon nitride.

8. The structure of claim 1, wherein
the mandrel layer comprises carbon containing material, and
the second etch process comprises an etch process using an oxygen containing etching gas.

9. An underlayer for use in forming a structure, comprising:
a first material formed on a substrate, wherein the first material is resistant to etching gases used in a first etch process to remove portions of a second material formed on the first material.

10. The underlayer of claim 9, wherein
the second material comprises silicon nitride,
the first material comprises at least one of aluminum oxide, tin oxide, boron, and tungsten carbide, and
the first etch process comprises an etch process using a fluorine containing etching gas.

11. The underlayer of claim 9, wherein
the second material comprises doped silicon containing material,
the first material comprises aluminum oxide, and
the first etch process comprises an etch process using a chlorine containing etching gas.

12. The underlayer of claim 9, wherein
the second material comprises silicon oxide,
the first material comprises at least one of aluminum oxide, tin oxide, boron, or silicon nitride, and
the first etch process comprises an etch process using a fluorine containing etching gas.

13. A method for forming a structure on a substrate, the method comprising:
performing a deposition process, comprising conformally depositing a spacer layer on a mandrel layer and a surface of an underlayer that is exposed from the mandrel layer; and
performing a first etch process, comprising removing portions of the spacer layer from a top surface of the mandrel layer and the surface of the under layer without removing the spacer layer from sidewalls of the mandrel layer,
wherein the underlayer is resistant to etching gases used in the first etch process.

14. The method of claim 13, wherein
the spacer layer comprises silicon nitride, and
the first etch process comprises an etch process using a fluorine containing etching gas.

15. The method of claim 14, wherein
the underlayer comprises at least one of aluminum oxide, tin oxide, boron, or tungsten carbide.

16. The method of claim 13, wherein
the spacer layer comprises doped silicon containing material, and
the first etch process comprises an etch process using a chlorine containing etching gas.

17. The method of claim 16, wherein
the underlayer comprises aluminum oxide.

18. The method of claim 13, wherein
the spacer layer comprises silicon oxide,
the first etch process comprises an etch process using a fluorine containing etching gas, and
the underlayer comprises at least one of aluminum oxide, tin oxide, boron, or silicon nitride.

19. The method of claim 13, further comprising:
performing a second etch process, comprising removing the mandrel layer without removing the spacer layer, wherein
the underlayer is resistant to etching gases used in the second etch process,
the mandrel layer comprises carbon containing material, and
the second etch process comprising an etch process using an oxygen containing etching gas.

20. The method of claim 13, wherein there is no recess formed in the underlayer.
